(19) United States
(12) Patent Application Publication
(10) Pub. No.: US 2002/0163760 A1
(43) Pub. Date: Nov. 7, 2002

(54) Disaster recovery tape drive

(76) Inventors: Alan M. Lindsey, Houston, TX (US); Kyle A. Walczak, Houston, TX (US)

Correspondence Address: CONLEY & ROSE & TAYON, P O BOX 3267, HOUSTON, TX, 77253-3267, US

(21) Appl. No.: 09/850,441

(22) Filed: May 7, 2001

(51) Int. Cl. G06F 9/00; G06F 9/24; G06F 9/445; H05K 10/00; G06F 15/177; H03K 19/003; G06F 9/455; G11B 5/78

(52) U.S. Cl. 360/134; 713/2; 714/2

(57) ABSTRACT

A tape drive assembly includes a tape drive adapted to receive a tape cartridge and control electronics. The control electronics are adapted to identify whether the tape cartridge comprises a disaster recovery tape, identify a disaster recovery request, and configure the tape drive as a bootable device in response to identifying the disaster recovery request. A method for restoring a computer having a tape drive includes autonomously determining whether a tape cartridge inserted into the tape drive comprises a disaster recovery tape; identifying a disaster recovery request; and configuring the tape drive to emulate a bootable device in response to identifying the disaster recovery request.

### BACKGROUND OF THE INVENTION

1. Field of the Invention

This invention relates generally to computer systems and, more particularly, to a bootable tape drive useful for disaster recovery.

2. Description of the Related Art

Computer systems are subject to any number of operational and environmental faults, ranging from disk failures and power outages to earthquakes and floods. While repair or replacement of damaged equipment is costly, the interruption of access to critical data may be far more severe. For this reason, businesses are taking great precautions to ensure the availability of their data and their systems. In the industry, this is sometimes referred to as “disaster recovery” (i.e., the ability to restore the computer system to operational status with as little loss in data and operation as possible). The term “disaster” in this context refers to those conditions that quickly come to mind like flood, fire, earthquake, tornado, etc., and their attendant havoc. However, it also refers to more mundane events, such as data and/or applications destroyed or contaminated by equipment failures, viruses, vandalism, etc. Thus, the term “disaster” refers to any condition, natural or man-made, that substantially interferes with the operation or content of a computer system (i.e., a system failure).

A common guard used against failure is replication. By replicating a system component, a spare is ready to take over if the primary should fail. Replication can occur at many levels, according to the faults it guards against. A typical way to replicate only data includes using tape backups. Tape backups are a popular replication strategy because they are simple and inexpensive. Tape backups ensure that data is safe if a disk or entire machine is damaged or destroyed. Further, if tapes are taken off-site or stored in a protective vault, tape backups can protect data against site-wide disasters. Typical tape backups only guard against the ultimate unavailability—data loss.

Disaster recovery and “guard-against-failure” techniques can be affected by a computer system's architecture. Many computer systems are organized in a server-client relationship. A centralized server coordinates the functions of the computer system and allows the clients to intercommunicate and share resources. Servers often link internal networks (i.e., “intranets”) and external networks (e.g., the Internet). A server failure is especially costly, because of the potential for data loss and the crippling of the connectivity across the computer system. A server may crash, fail to reboot, or it may recover but not function as expected. All of these possibilities are potential consequences of a “disaster.”

A company can lose most or all of its data under these situations unless a disaster recovery strategy is implemented. If a complete backup has been done before the failure, then the questions become how long will it take to get the data back, how long will the system be down, and how easily is the recovery completed. Conventional disaster recovery methods can take 4 to 10 hours to return a system to the original, pre-disaster state. Although the replacement of failed components may only take a few minutes, installing the operating system and restoring the data usually takes considerably longer. For example, it takes approximately three hours to install just the Windows® NT 4.0 operating system. This time does not include the additional time needed to install all of the other applications and restore the data. Prolonged disaster recovery costs a business in time and revenue.

One other aspect of disaster recovery procedures is that relatively large number and types of program storage media employed. Preparing for recovery in a Microsoft® NT environment, for instance, typically involves creating a series of bootable diskettes (three to five diskettes depending on the vendor software used) using the Microsoft® Windows® NT compact disc, read only memory (“CD-ROM”) disk; creating a tape backup of the computer system; updating the bootable diskettes every time the system configuration changes; and storing these diskettes where they will be readily available if needed. The procedure for restoring a system includes: retrieving the bootable diskettes and tapes; retrieving the Microsoft® Windows® NT CD-ROM; booting the system from diskette for disaster recovery; restoring the Windows® NT base system from the CD-ROM; and finally restoring the remaining portions of the Windows® NT system from tape.

Thus, conventional disaster recovery methods are lengthy and time consuming. The methods use several different types of media (CDs, diskettes, and tapes) to restore the server to the state it was in before the failure occurred, which increases the chances for an unsuccessful restore of the system. For example, the media can be faulty, the diskettes or CDs not current, or parts of the disaster recovery media can be misplaced. This and other features contribute to the costly downtime of a computing system in the event of a “disaster.”

The present invention is directed to overcoming, or at least reducing the effects of, one or more of the problems set forth above.

### SUMMARY OF THE INVENTION

One aspect of the present invention is seen in a tape drive assembly including a tape drive adapted to receive a tape cartridge and control electronics. The control electronics are adapted to identify whether the tape cartridge comprises a disaster recovery tape, identify a disaster recovery request, and configure the tape drive as a bootable device in response to identifying the disaster recovery request.

Another aspect of the present invention is seen in a method for restoring a computer having a tape drive. The method includes autonomously determining whether a tape cartridge inserted into the tape drive comprises a disaster recovery tape; identifying a disaster recovery request; and configuring the tape drive to emulate a bootable device in response to identifying the disaster recovery request.

### BRIEF DESCRIPTION OF THE DRAWINGS

The invention may be understood by reference to the following description taken in conjunction with the accompanying drawings, in which like reference numerals identify like elements, and in which:

FIG. 1 is a simplified, conceptualized, block diagram of a computer system employing a disaster recovery tape drive in accordance with a first illustrative embodiment of the present invention;

FIG. 2 is front, plan view of an exemplary disaster recovery tape drive used in the system of FIG. 1;

FIG. 3 is a simplified flow diagram of a method for restoring the server in the system of FIG. 1 with a disaster recovery operation in accordance with a second illustrative embodiment of the present invention; and

FIG. 4 is a simplified flow diagram of a method for initiating a disaster recover event that may be employed in the method of FIG. 3.

While the invention is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION OF SPECIFIC EMBODIMENTS

Illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

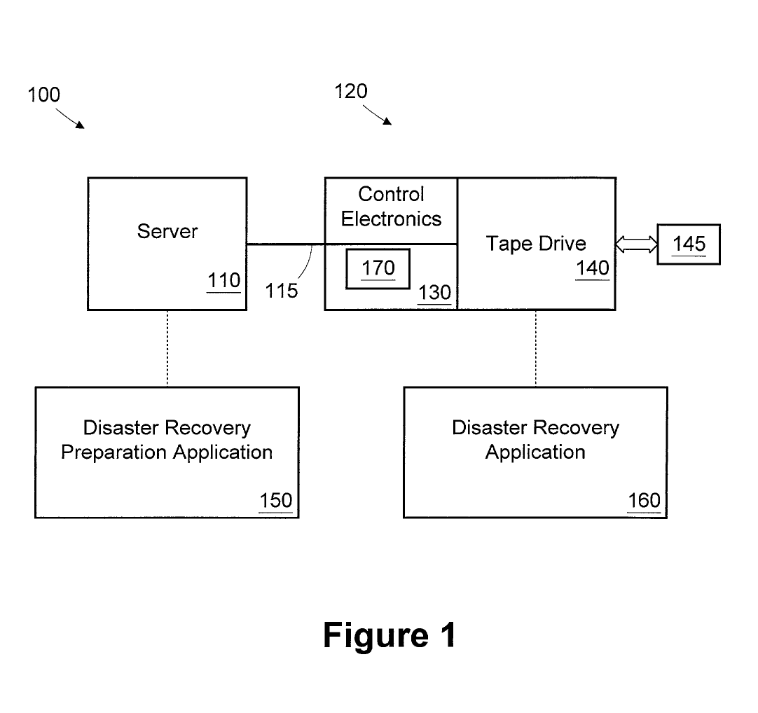

Turning now to the drawings, and first to FIG. 1, a simplified block diagram of a computer system 100 is provided. The computer system 100 includes a server 110 coupled to a tape drive assembly 120. Although this particular embodiment employs a server 110, this is not necessary to the practice of the invention. The server 110 may be, in alternative embodiments, any type of electronic computing device as may be found in a computing system. The tape drive assembly 120 includes control electronics 130 and a tape drive 140 for receiving a disaster recovery (DR) tape 145. The control electronics 130 include firmware (not shown) that controls a disaster recovery event using the tape drive 140. During a disaster recovery event, the tape drive assembly 120 functions as a bootable device to allow restoration of the server without the need for multiple restoration media.

The tape drive assembly 120 may be installed as an internal device on the server 110 or as an external device, as in the embodiment of FIG. 1. In an internal implementation (not shown), the control electronics 130 may be installed as an expansion card on a bus (e.g., a small computer system interface, or “SCSI”, bus) within the server 110. In an external implementation, the control electronics 130 and tape drive 140 may be housed in a single enclosure and coupled to the server 110 by an interface cable 115.

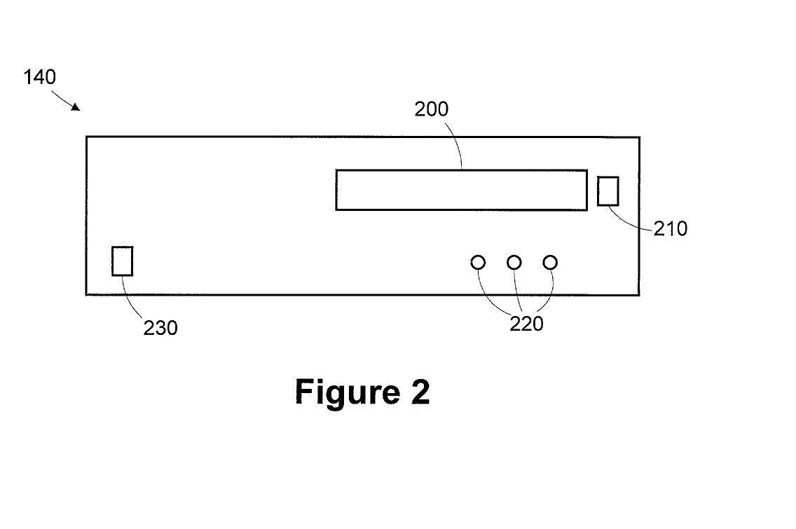

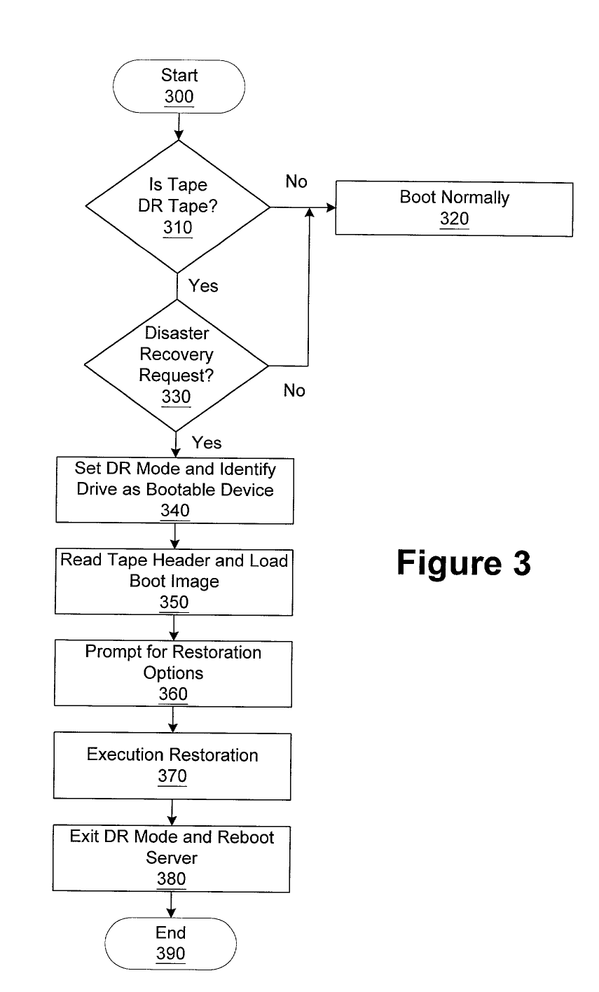

The operation of the tape drive assembly 120 during a disaster recovery event is described in greater detail below in reference to FIGS. 2 and 3. FIG. 2 is a front, plan view of an exemplary embodiment of the tape drive assembly 120 in FIG. 1. FIG. 3 is a simplified flow diagram of a method for restoring the server 110 with a disaster recovery operation using the tape drive assembly 120. Referring to FIG. 2, the tape drive 140 includes a slot 200 for receiving a tape cartridge, an eject button 210 for ejecting an inserted tape cartridge, status lights 220, and a power switch 230. For simplicity and ease of illustration, the power switch 230 is illustrated on the front of the tape drive 140, while in an actual embodiment, the power switch may be located on the side or rear of the tape drive 140. If the tape drive 140 is mounted internally in the server 110, no power switch 230 may be present at all, since power would be provided and controlled by the server 110. These features of the tape drive 140 may be implemented using conventional techniques known to the art.

To prepare for a disaster recovery, a user first backs up the server 110 before the disaster occurs using a bootable disaster recovery tape. The user inserts a tape cartridge (not shown) into the slot 200 of the tape drive 140 and executes a disaster recovery preparation application 150 residing on the server 110. The disaster recovery preparation application 150 determines if the tape drive assembly 120 can support a disaster recover event and prompts the user to determine if a normal disaster recovery tape or the bootable DR tape 145 is desired. The user selects the bootable option and the application 150 builds a bootable image and backs up the server 110. The backup includes system files necessary to boot the server 110.

Techniques for transferring the system files necessary to make the disaster recovery tape bootable and for performing the backup of the server 110 are well know to those of ordinary skill in the art, and are not described in greater detail herein for clarity and so as not to obscure the invention. After completion of the backup process, the DR tape 145 is write-protected and stored for future use. An exemplary disaster recovery preparation application 150 suitable for use in the context described herein is Backup Exec V.8.5 for Microsoft Windows® NT 4.0 offered by VERITAS Software at 1600 Plymouth Street, Mountain View, Calif. 94043.

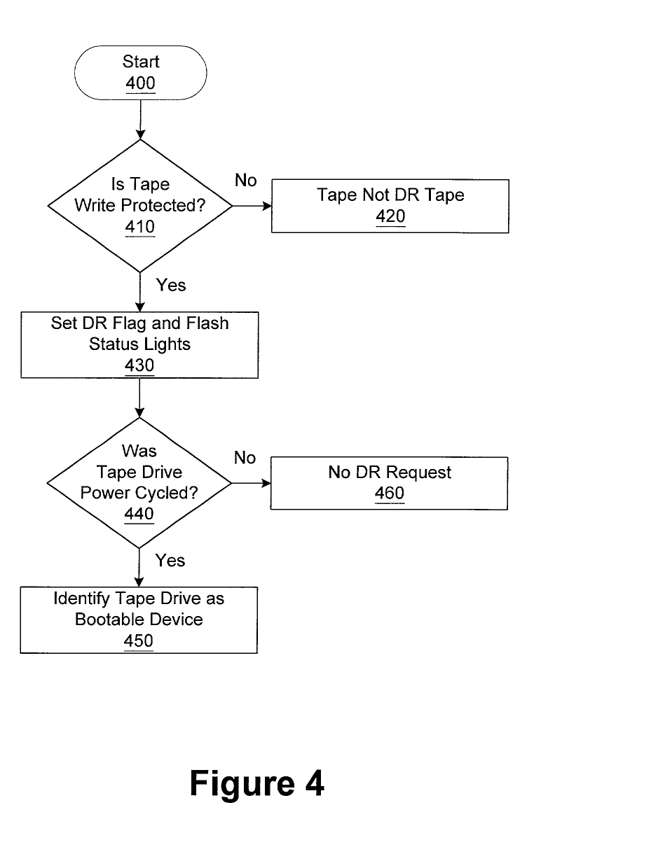

Turning now to FIGS. 1 and 3, a method for restoring the server 110 after a system failure in accordance with the present invention is described. The method starts in block 300. In block 310, it is determined (e.g., by the control electronics 130) whether the tape cartridge (not shown) inserted into the tape drive 140 is a DR tape 145. One technique for determining whether the tape cartridge is a DR tape 145 is to determine whether it is write protected, in which case it is then assumed to be a DR tape 145. A particular technique for both identifying the DR tape 145 and detecting a disaster recovery request is described in greater detail below in reference to FIG. 4.

If the tape cartridge is not a DR tape 145, the server 110 boots normally in block 320 and the computer system begins normal operation. If the tape cartridge is a DR tape 145, the control electronics 130 determine if a disaster recovery request has been initiated in block 330. Again, if no disaster recovery request is identified, the server 110 boots normally in block 320 and the computer system begins normal operation. If a disaster recovery request is identified in block 330, the control electronics 130 initiate a disaster recover mode and identify the tape drive 140 as a bootable device in block 340.

One technique for identifying the tape drive 140 as a bootable device is for the control electronics 130 to notify the server 110 during the initialization sequence that the tape drive 140 is a typical bootable device, such as a floppy drive, a hard disk, or a bootable CD-ROM drive. The particular technique used to emulate a bootable device depends on the specific configuration of the server 110 and the operating system used. Typically, during the initialization sequence of the server 110, the server 110 determines the identity of the devices (e.g., the tape drive 140) attached thereto. In response to a query from the server 110, each device responds with a code that includes the device type.

Different codes are defined for floppy drives, hard disk drives, CD-ROM drives, tape drives, etc. An exemplary technique for identifying a CD-ROM as a bootable device, that may be employed to identify the tape drive 140 as a bootable device, is described in the “‘El Torito’ Bootable CD-ROM Format Specification, Version 1.0,” dated Jan. 25, 1995, proffered by Phoenix Technologies and IBM, and incorporated herein by reference in its entirety. Thus, in one embodiment, the tape drive 140 is configured to emulate a bootable CD-ROM drive. However, the tape drive 140 may be configured to emulate other types of bootable device in alternative embodiments.

To allow the server 110 to recognize the tape drive 140 as a bootable device, the initialization routine may require modification. In typical computer systems, the initialization routine has a time-out interval associated with each device type. If a particular device, does not respond within the time out interval, the server 110 does not recognize the device as being bootable and proceeds to the next device. Typically, the time out interval for a CDROM drive is about 8 seconds. A typical tape drive is much slower than a typical CD-ROM drive, and would not be able to respond within the requisite time out interval. Thus, the time out interval used by the server 110 to identify bootable devices is set at a value high enough to allow the tape drive 140 to respond. For example, the time out interval may be set to between about 30 and 120 seconds. In the illustrated embodiment, the time out interval is about 90 seconds. Note that the server 110 will recognize the tape drive 140 as a bootable device only upon a reboot of the server 110.

Returning to FIGS. 1 and 3, in block 350, the server 110 reads a tape header (not shown) on the DR tape 145 and loads a boot image stored thereon. DR backup data is stored on the DR tape 145 following the boot image. The DR backup data is formatted similar to a typical tape backup file. Specific techniques for configuring the tape headers and boot images are well known to those of ordinary skill in the art. During the boot process, the server 110 loads a disaster recovery application 160 (see FIG. 1) from the DR tape 145 and executes the disaster recovery application 160 to perform the recovery operation. An exemplary disaster recovery application 160 suitable for use in the context described herein is Backup Exec V.8.5 for Microsoft Windows®NT 4.0 offered by VERITAS Software.

In block 360, the disaster recovery application 160 prompts the user for restoration options. For example, the user may choose to modify the partitioning of the hard disk (not shown) in the server 110. The user may also select the particular backup file stored on the DR tape 145 to use for the restoration. In block 370, the disaster recovery application 160 executes the restoration using the backup data stored on the DR tape 145 and restores the server 110 to the pre-failure condition. In block 380, the DR tape 145 is ejected, the control electronics 130 exit the DR mode, and the disaster recovery application 160 reboots the server 110. The method concludes in block 390.

Turning now to FIG. 4, an exemplary embodiment of the technique used by the control electronics 130 to identify the DR tape 145 and detect a disaster recovery request (i.e., asset forth in blocks 310 and 330 of FIG. 3) is shown. The method starts in block 400. In block 410, the control electronics 130 analyze an inserted tape cartridge to determine if it is write-protected. If the tape cartridge is not write-protected, the control electronics 130 determine that the tape is not a DR tape 145 in block 420 and the server 100 boots normally (i.e., as in block 320 of FIG. 3). If the control electronics 130 determine that the tape cartridge is a DR tape 145, it sets a DR flag (not shown) in a non-volatile memory 170 (see FIG. 1) to enter DR mode in block 430.

The control electronics 130, in this particular embodiment, then flash the status lights 220 (see FIG. 2) in block 430 responsive to the determination that the cartridge tape is a DR tape 145, although this is not necessary to the practice of the invention in all embodiments. The status lights 220 flash for a predetermined time interval (e.g., between about 5 and 30 seconds) to indicate to a user that a disaster recovery is possible. In the illustrated embodiment, the predetermined time interval is about 15 seconds. If during the time interval that the status lights 220 are flashing, the user cycles power to the tape drive assembly 120, the control electronics 130 identify a disaster recovery request in block 440. The user may cycle the power to the tape drive assembly 120 using the power switch 230 for an external installation or by cycling power to the server 110 in an internal installation. When power is restored to the tape drive 140, the control electronics 130 identify that the DR flag had been previously set in the non-volatile memory 170 and initiate a disaster recovery by identifying the tape drive 140 as a bootable device in block 450. If the user does not cycle power to the tape drive 140 during the predetermined interval, the DR tape flag is cleared, and the control electronics 130 do not identify a DR request in block 460 and the server 110 boots normally (i.e., as in block 320 of FIG. 3). If power is cycled to the tape drive assembly 120 during the performance of the methods of FIGS. 3 and 4, the DR tape flag is maintained in the non-volatile memory 170, and the disaster recovery may proceed. However, if the tape cartridge is ejected, the control electronics 130 clear the flag and during a subsequent boot of the server 110 the control electronics 130 would not identify the tape drive 140 as a bootable device.

The particular embodiments disclosed above are illustrative only, as the invention may be modified and practiced in different but equivalent manners apparent to those skilled in the art having the benefit of the teachings herein. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A tape drive assembly, comprising:
a tape drive adapted to receive a tape cartridge; and
control electronics adapted to identify whether the tape cartridge comprises a disaster recovery tape, identify a disaster recovery request, and configure the tape drive as a bootable device in response to identifying the disaster recovery request.

2. The tape drive assembly of claim 1, wherein the control electronics are adapted to determine that the tape cartridge comprises a disaster recovery tape in response to the tape cartridge being write-protected.

3. The tape drive assembly of claim 1, wherein the tape drive includes a status light, and the control electronics are adapted to flash the status light in response to determining that the tape cartridge comprises a disaster recovery tape.

4. The tape drive assembly of claim 3, wherein the control electronics are adapted to flash the status light for a predetermined time interval.

5. The tape drive assembly of claim 3, wherein the control electronics are adapted to identify the disaster recovery request in response to the tape drive assembly being power-cycled while the status light is flashing.

6. The tape drive assembly of claim 1, wherein the control electronics are adapted to configure the tape drive as a bootable device by configuring the tape drive to emulate a bootable CD-ROM device.

7. The tape drive assembly of claim 1, wherein the control electronics include a non-volatile memory, and the control electronics are adapted to set a disaster recovery flag in response to determining that the tape cartridge comprises the disaster recovery tape.

8. The tape drive assembly of claim 7, wherein the control electronics are adapted to clear the disaster recovery flag in response to not identifying the disaster recovery request.

9. A tape drive assembly, comprising:
a tape drive adapted to receive a tape cartridge and including a status light; and
control electronics adapted to identify whether the tape cartridge comprises a disaster recovery tape, flash the status light in response to determining that the tape cartridge comprises a disaster recovery tape, identify a disaster recovery request in response to the tape drive assembly being power-cycled while the status light is flashing, and configure the tape drive as a bootable device in response to identifying the disaster recovery request.

10. The tape drive assembly of claim 9, wherein the control electronics are adapted to determine that the tape cartridge comprises a disaster recovery tape in response to the tape cartridge being write-protected.

11. The tape drive assembly of claim 9, wherein the control electronics are adapted to flash the status light for a predetermined time interval.

12. The tape drive assembly of claim 9, wherein the control electronics are adapted to configure the tape drive as a bootable device by configuring the tape drive to emulate a bootable CD-ROM device.

13. The tape drive assembly of claim 9, wherein the control electronics include a non-volatile memory, and the control electronics are adapted to set a disaster recovery flag in response to determining that the tape cartridge comprises the disaster recovery tape.

14. The tape drive assembly of claim 13, wherein the control electronics are adapted to clear the disaster recovery flag in response to not identifying the disaster recovery request.

15. A computer system, comprising:
a computer; and
a tape drive assembly coupled to the computer, comprising:
a tape drive adapted to receive a tape cartridge; and
control electronics adapted to identify whether the tape cartridge comprises a disaster recovery tape, identify a disaster recovery request, and configure the tape drive as a bootable device in response to identifying the disaster recovery request.

16. The system of claim 15, wherein the control electronics are adapted to determine that the tape cartridge comprises a disaster recovery tape in response to the tape cartridge being write-protected.

17. The system of claim 15, wherein the tape drive includes a status light, and the control electronics are adapted to flash the status light in response to determining that the tape cartridge comprises a disaster recovery tape.

18. The system of claim 17, wherein the control electronics are adapted to flash the status light for a predetermined time interval.

19. The system of claim 17, wherein the control electronics are adapted to identify the disaster recovery request in response to the tape drive assembly being power-cycled while the status light is flashing.

20. The system of claim 15, wherein the control electronics are adapted to configure the tape drive as a bootable device by configuring the tape drive to emulate a bootable CD-ROM device.

21. The system of claim 15, wherein the computer is adapted to recognize a response from the tape drive assembly based on a predetermined time out interval.

22. The system of claim 21, wherein the predetermined time out interval is between about 30 and 120 seconds.

23. The system of claim 15, wherein the control electronics include a non-volatile memory, and the control electronics are adapted to set a disaster recovery flag in response to determining that the tape cartridge comprises the disaster recovery tape.

24. The system of claim 23, wherein the control electronics are adapted to clear the disaster recovery flag in response to not identifying the disaster recovery request.

25. A computer system, comprising:
a computer; and
a tape drive assembly coupled to the computer, comprising:
a tape drive adapted to receive a tape cartridge and having a status light; and
control electronics adapted to identify whether the tape cartridge comprises a disaster recovery tape, flash the status light in response to determining that the tape cartridge comprises a disaster recovery tape, identify a disaster recovery request in response to the tape drive assembly being power-cycled while the status light is flashing, and configure the tape drive as a bootable device in response to identifying the disaster recovery request.

26. The system of claim 25, wherein the control electronics are adapted to determine that the tape cartridge comprises a disaster recovery tape in response to the tape cartridge being write-protected.

27. The system of claim 25, wherein the control electronics are adapted to flash the status light for a predetermined time interval.

28. The system of claim 25, wherein the control electronics are adapted to configure the tape drive as a bootable device by configuring the tape drive to emulate a bootable CD-ROM device.

29. The system of claim 25, wherein the computer is adapted to recognize a response from the tape drive assembly based on a predetermined time out interval.

30. The system of claim 29, wherein the predetermined time out interval is between about 30 and 120 seconds.

31. The system of claim 25, wherein the control electronics include a non-volatile memory, and the control electronics are adapted to set a disaster recovery flag in response to determining that the tape cartridge comprises the disaster recovery tape.

32. The system of claim 31, wherein the control electronics are adapted to clear the disaster recovery flag in response to not identifying the disaster recovery request.

33. A method for restoring a computer having a tape drive, comprising:
autonomously determining whether a tape cartridge inserted into the tape drive comprises a disaster recovery tape;
identifying a disaster recovery request; and
configuring the tape drive to emulate a bootable device in response to identifying the disaster recovery request.

34. The method of claim 33, wherein determining whether the tape cartridge comprises a disaster recovery tape further comprises determining if the tape cartridge is write-protected.

35. The method of claim 33, wherein the tape drive includes a status light, and the method further comprises flashing the status light in response to determining that the tape cartridge comprises a disaster recovery tape.

36. The method of claim 35, wherein flashing the status light comprises flashing the status light for a predetermined time interval.

37. The method of claim 35, wherein identifying the disaster recovery request comprises identifying the disaster recovery request in response to the tape drive being power-cycled while the status light is flashing.

38. The method of claim 33, wherein configuring the tape drive as the bootable device comprises configuring the tape drive as the bootable device by configuring the tape drive to emulate a bootable CD-ROM device.

39. The method of claim 33, further comprising setting a disaster recovery flag in a non-volatile memory in response to determining that the tape cartridge comprises the disaster recovery tape.

40. The method of claim 39, further comprising clearing the disaster recovery flag in response to not identifying the disaster recovery request.

41. A method for restoring a computer having a tape drive, comprising:
autonomously determining whether a tape cartridge inserted into the tape drive comprises a disaster recovery tape;
flashing a status light of the tape drive in response to determining that the tape cartridge comprises a disaster recovery tape;
identifying a disaster recovery request in response to the tape drive being power-cycled while the status light is flashing; and
configuring the tape drive as a bootable device in response to identifying the disaster recovery request.

42. The method of claim 41, wherein determining whether the tape cartridge comprises a disaster recovery tape comprises determining if the tape cartridge is write-protected.

43. The method of claim 41, wherein flashing the status light comprises flashing the status light for a predetermined time interval.

44. The method of claim 41, wherein configuring the tape drive as the bootable device comprises configuring the tape drive as the bootable device by configuring the tape drive to emulate a bootable CD-ROM device.

45. The method of claim 41, further comprising setting a disaster recovery flag in a non-volatile memory in response to determining that the tape cartridge comprises the disaster recovery tape.

46. The method of claim 45, further comprising clearing the disaster recovery flag in response to not identifying the disaster recovery request.

47. A system for restoring a computer having a tape drive, comprising:
means for autonomously determining whether a tape cartridge inserted into the tape drive comprises a disaster recovery tape;
means for identifying a disaster recovery request; and
means for configuring the tape drive as a bootable device in response to identifying the disaster recovery request.

48. A system for restoring a computer having a tape drive, comprising:
means for autonomously determining whether a tape cartridge inserted into the tape drive comprises a disaster recovery tape;
means for flashing a status light of the tape drive in response to determining that the tape cartridge comprises a disaster recovery tape;
means for identifying a disaster recovery request in response to the tape drive being power-cycled while the status light is flashing; and
means for configuring the tape drive as a bootable device in response to identifying the disaster recovery request.
